(19) United States
(12) Patent Application Publication
(10) Pub. No.: US 2024/0213111 A1
(43) Pub. Date: Jun. 27, 2024

(54) CONFIGURABLE MICRO HEAT PIPE (MHP) AND MICROCHANNEL FOR IMPROVED COOLING OF GLASS CORE SUBSTRATE

(71) Applicant: Intel Corporation, Santa Clara, CA (US)

(72) Inventors: Mohammad Mamunur RAHMAN, Gilbert, AZ (US); Je-Young CHANG, Tempe, AZ (US); Jeremy D. ECTON, Gilbert, AZ (US); Rahul N. MANEPALLI, Chandler, AZ (US); Srinivas V. PIETAMBARAM, Chandler, AZ (US); Gang DUAN, Chandler, AZ (US); Brandon C. MARIN, Gilbert, AZ (US); Suddhasattwa NAD, Chandler, AZ (US)

(21) Appl. No.: 18/088,360

(22) Filed: Dec. 23, 2022

(51) Int. Cl. H01L 23/367; G06F 1/20; H01L 23/15; H01L 23/427; H01L 23/473; H01L 23/498

(52) U.S. Cl. CPC H01L 23/367; G06F 1/20; H01L 23/15; H01L 23/427; H01L 23/473; H01L 23/49816

(57) ABSTRACT

Embodiments disclosed herein include electronic packages. In an embodiment, the electronic package comprises a core with a first surface and a second surface opposite from the first surface, and where the core comprises glass. In an embodiment, a channel is disposed into the first surface of the core, and a lid is provided over the channel. In an embodiment, the lid seals the channel between a first end and a second end of the channel.

### TECHNICAL FIELD

Embodiments of the present disclosure relate to electronic packages, and more particularly to package architectures that include a glass core with a micro heat pipe (MHP) and/or microchannels for improved cooling of the glass core.

### BACKGROUND

The heat generation from glass core substrate packages can be highly non-uniform with areas of high local heat fluxes at a few locations proximate to dies and/or passive components (e.g., inductors) in the substrate. These localized high heat flux areas are commonly known as “hot spots”. The demands for more efficient heat removal from the hot spots are compelling. Specifically, stacked-die devices, including 3D through silicon via (TSV) assemblies, are more difficult to cool. While the top die in the 3D stack may be placed in intimate thermal contact with a heat spreader, heat sink, or heat pipe, the interposed die (i.e., the die sandwiched between the substrate and the top die) does not have a low resistance thermal path to dissipate heat. Poor heat rejection from the interposed die places severe design constraints on next-generation 3D TSV stacked die architectures. Particularly, such solutions dictate that high-power dies (e.g., XPU) must be placed on top of the stack.

### BRIEF DESCRIPTION OF THE DRAWINGS

FIGS. 1A-1H are cross-sectional illustrations depicting a process for forming microchannels in a glass core substrate, in accordance with an embodiment.

FIGS. 2A-2K are cross-sectional illustrations depicting a process for forming heat pipes in a glass core substrate, in accordance with an embodiment.

FIGS. 3A-3E are cross-sectional illustrations depicting a process for forming microchannels with triangular shaped trenches in a glass core substrate, in accordance with an embodiment.

FIGS. 4A-4K are cross-sectional illustrations depicting a process for forming heat pipes with triangular trenches in a glass core substrate, in accordance with an embodiment.

FIGS. 5A-5G are cross-sectional illustrations depicting a process for forming heat pipes in a multi-layer glass core, in accordance with an embodiment.

FIG. 6 is a cross-sectional illustration of a glass core with a heat pipe and thermally conductive pillars in a glass core, in accordance with an embodiment.

FIG. 7 is a cross-sectional illustration of a computing system with a glass core that includes a heat pipe, in accordance with an embodiment.

FIG. 8 is a schematic of a computing device built in accordance with an embodiment.

### EMBODIMENTS OF THE PRESENT DISCLOSURE

Described herein are package architectures that include a glass core with a micro heat pipe (MHP) and/or microchannels for improved cooling of the glass core, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, glass core architectures are thermally limited since the lower dies are not able to be coupled to a low thermal resistance path in order to minimize hot spots. To optimize performance of glass core substrate products, flexibility to have heat pipes (or micro channels) embedded in the substrate is strongly desired. This can provide intimately located thermal paths to dissipate heat to the bottom side. Use of heat pipes (or micro channels) have been explored. However, the integration methodology of those structures in glass core substrate manufacturing processes have not been well defined.

Accordingly, embodiments disclosed herein include micro channel and heat pipe architectures that are integrated into the glass core. The micro channels may include an inlet and an outlet. As such, a cooling fluid may be flown through the micro channels. In one embodiment, micro channels may be formed by providing trenches into the surface of the glass core. The micro channels are then filled with a sacrificial material and a lid is formed over the micro channels. After the lid is formed, the sacrificial material is removed to form fluidic channels. The trenches may have vertical sidewalls or they may have a triangular shape.

In another embodiment, heat pipes are embedded in the glass core. The heat pipes may be a closed system. That is, there is no inlet and outlet. The cooling fluid in the heat pipe transfer heat along the length of the heat pipe in order to more evenly distribute thermal energy within the glass core. In an embodiment, the heat pipes may be formed with a process similar to the process used to form the micro channels. However, after the cooling fluid is inserted into the heat pipes, the ends are closed with a hermetic seal. The trenches for the heat pipes may have vertical sidewalls, or the trenches may be triangular shaped.

In yet another embodiment, micro channels or heat pipes can be made with a two layer glass core architecture. In an embodiment, a trench is formed into the surface of a first glass core layer. A second glass core layer is attached over the first glass core layer. Openings through the second glass core layer can be formed to connect to the trench. In an embodiment, the micro channels can be an open system with an inlet and an outlet. In a heat pipe embodiment, the ends of the pipe may be hermetically sealed after a cooling fluid is inserted into the pipe. Thermally conductive pillars may also be included in the glass core layers to further improve heat dissipation.

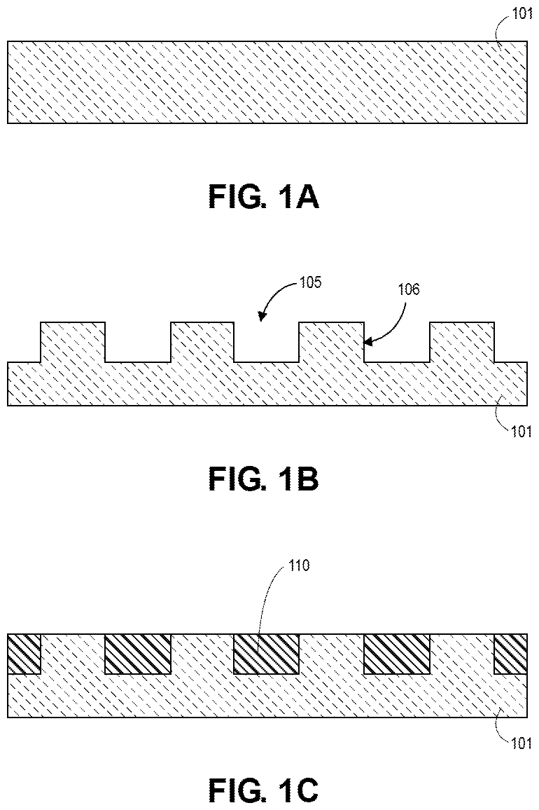

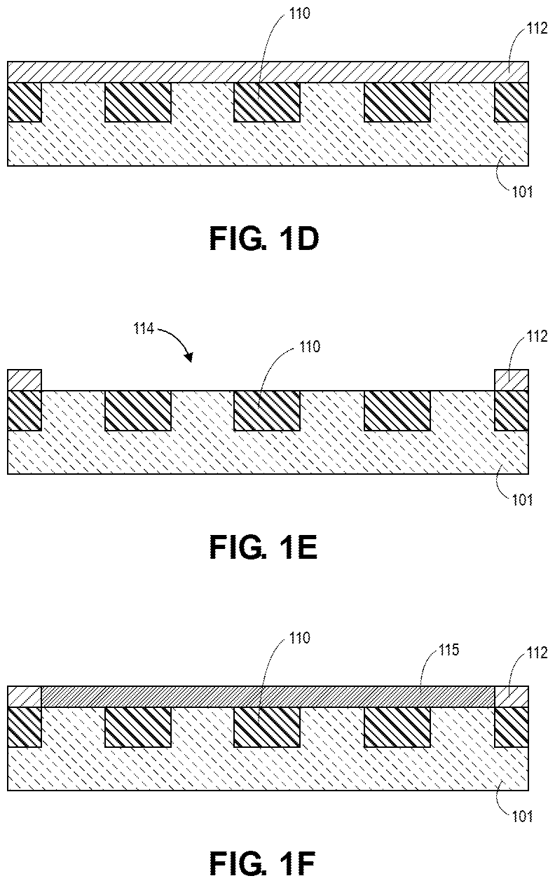

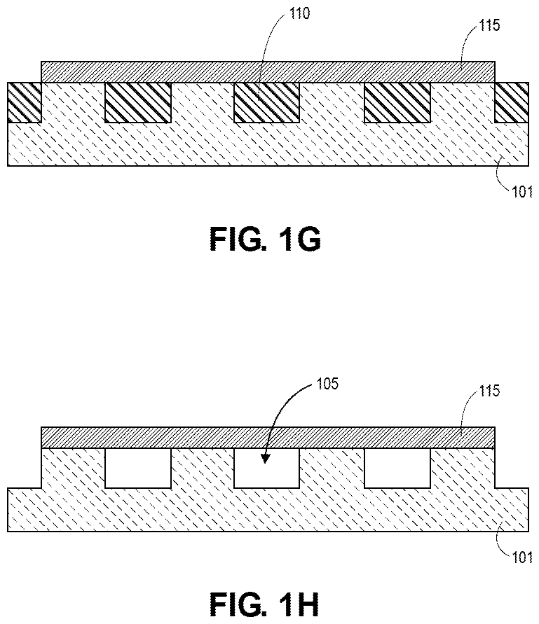

Referring now to FIGS. 1A-1H, a series of cross-sectional illustrations depicting a process for forming micro channels in a glass core is shown, in accordance with an embodiment. In an embodiment, the micro channels may be an open system. That is, a cooling fluid (e.g., water, etc.) may be flown into and out of the micro channels in order to cool the glass core. The micro channels may be provided proximate to one or more dies (not shown) or passive components (not shown) in order to remove heat from the system.

Referring now to FIG. 1A, a cross-sectional illustration of a glass core 101 is shown, in accordance with an embodiment. The glass core 101 may be any suitable glass formulation for making glass cores for package substrates. For example, the glass core 101 may comprise a borosilicate glass, a fused silica glass, or the like. In a particular embodiment, the glass core 101 is a glass formulation that is compatible with laser assisted etching processes. For example, laser exposure of the glass core 101 may result in a phase and/or microstructure change in the glass core 101 that renders the exposed regions more susceptible to an etching chemistry (e.g., a wet etching chemistry). In an embodiment, the glass core 101 may be any suitable thickness. For example, the glass core 101 may have a thickness that is between approximately 50 μm and approximately 1,000 μm. As used herein, “approximately” may refer to a range of values that are within ten percent of the stated value. For example, approximately 1,000 μm may refer to a range between 900 μm and 1,100 μm.

Referring now to FIG. 1B, a cross-sectional illustration of the glass core 101 after channels 105 are formed is shown, in accordance with an embodiment. The channels 105 may extend into a top surface of the glass core 101 without passing entirely through a thickness of the glass core 101. For example, the channels 105 may have a bottom surface and sidewall surfaces 106. The bottom surface may be substantially flat, and the sidewall surfaces 106 may be substantially vertical. In such an embodiment, the channels 105 may be referred to as having a rectangular shape. The channels 105 may extend into and out of the plane of FIG. 1B. In the illustrated embodiment, a set of five channels 105 are shown. Though, it is to be appreciated that one or more channels 105 may be used in some embodiments.

Referring now to FIG. 1C, a cross-sectional illustration of the glass core 101 after a sacrificial layer 110 is provided in the channels 105 is shown, in accordance with an embodiment. The sacrificial layer 110 may be used as a scaffolding on which a lid will be formed. The sacrificial layer 110 may be a dielectric material. In a particular embodiment, the sacrificial layer 110 is a material that is thermally decomposable. As such, after the lid is formed, the sacrificial layer 110 can be removed by heating the glass core 101. The sacrificial layer 110 may be deposited with any suitable deposition process, (e.g., lamination, printing, etc.). The top surfaces of the sacrificial layers 110 may be substantially coplanar with a top surface of the glass core 101. That is, the sacrificial layer 110 may be provided only within the channels 105 in some embodiments.

Referring now to FIG. 1D, a cross-sectional illustration of the glass core 101 after a resist layer 112 is disposed over the glass core 101 and the sacrificial layer 110 is shown, in accordance with an embodiment. The resist layer 112 may be a photoresist material, or any other similarly patternable material. In an embodiment, the resist layer 112 may be deposited with a spin-on process, a deposition process, or any other suitable process.

Referring now to FIG. 1E, a cross-sectional illustration of the glass core 101 after the resist layer 112 is patterned is shown, in accordance with an embodiment. In an embodiment, the resist layer 112 is patterned by exposure to an electromagnetic radiation source. The resist layer 112 is then developed to remove portions of the resist layer from over one or more of the channels 105. For example, an opening 114 exposes the three center channels 105 in FIG. 1E.

Referring now to FIG. 1F, a cross-sectional illustration of the glass core 101 after a lid 115 is formed over the glass core 101 and the sacrificial layer 110 is shown, in accordance with an embodiment. The lid 115 may be any suitable material that prevents diffusion or leaking of a cooling fluid that will be flown through the channels 105. For example, the lid 115 may comprise copper in some embodiments. The lid 115 may be deposited with any suitable deposition process. For example, an electroplating process, a physical vapor deposition (PVD) process, a chemical vapor deposition (CVD) process, or the like may be used in order to form the lid 115.

Referring now to FIG. 1G, a cross-sectional illustration of the glass core 101 after the resist layer 112 is removed is shown, in accordance with an embodiment. In an embodiment, the resist layer 112 may be removed with a resist stripping process, an ashing process, or any other suitable process.

Referring now to FIG. 1H, a cross-sectional illustration of the glass core 101 after the sacrificial layer 110 is removed is shown, in accordance with an embodiment. In an embodiment, the sacrificial layer 110 may be removed with a thermal decomposition process. For example, the glass core 101 may be placed in a volume that is maintained at an elevated temperature (e.g., approximately 200 degrees Celsius or higher). The sacrificial layer 110 decomposes and is removed out the inlet and/or outlet of the channels 105. After the sacrificial layer 110 is removed, a cooling fluid (e.g., water or the like) may be flown through the channels 105 in order to remove thermal energy from the system. The channels 105 in FIG. 1H may be referred to as micro channels in some embodiments, especially when the channels have a width and/or depth that is on the micron scale (e.g., 500 μm or less, 100 μm or less, or 20 μm or less).

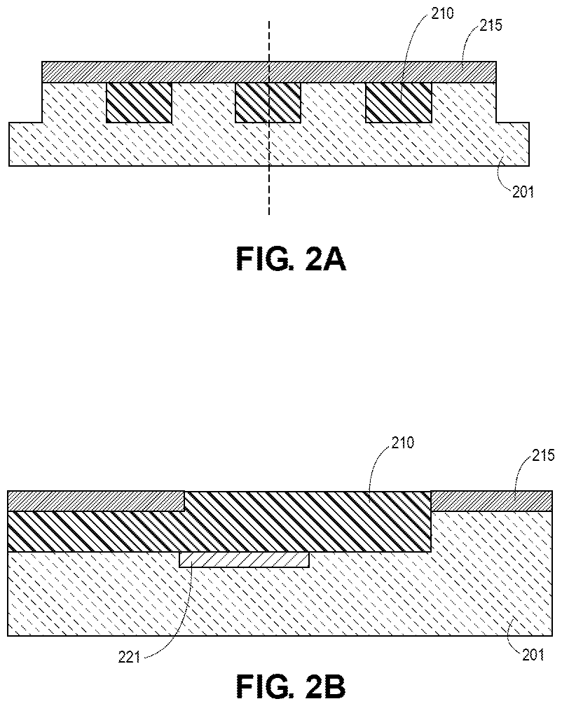

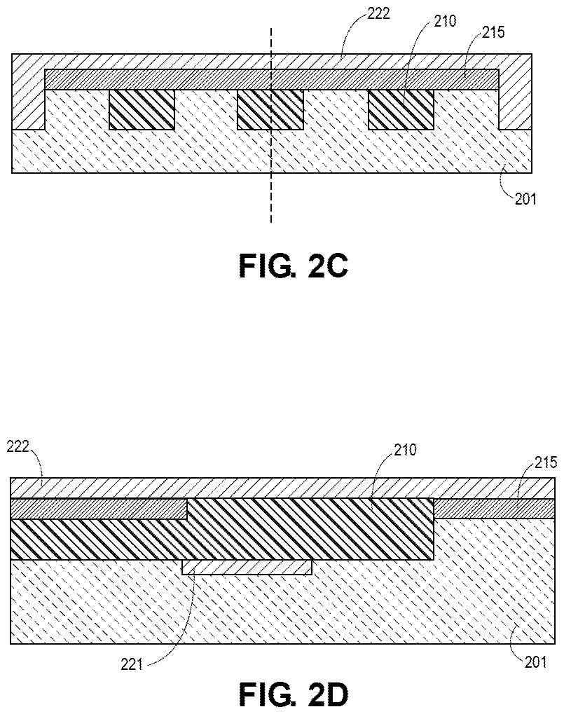

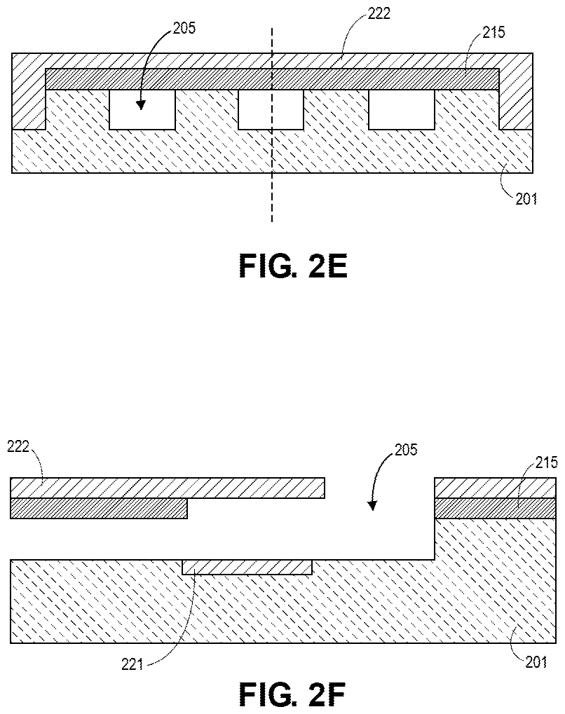

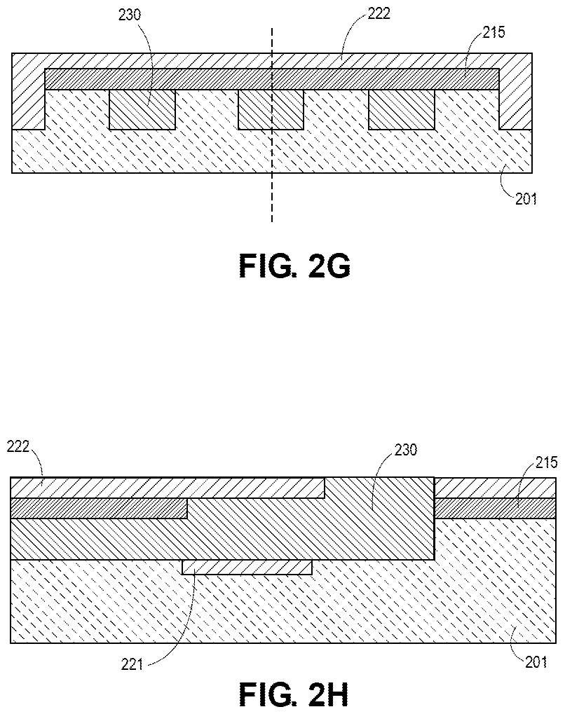

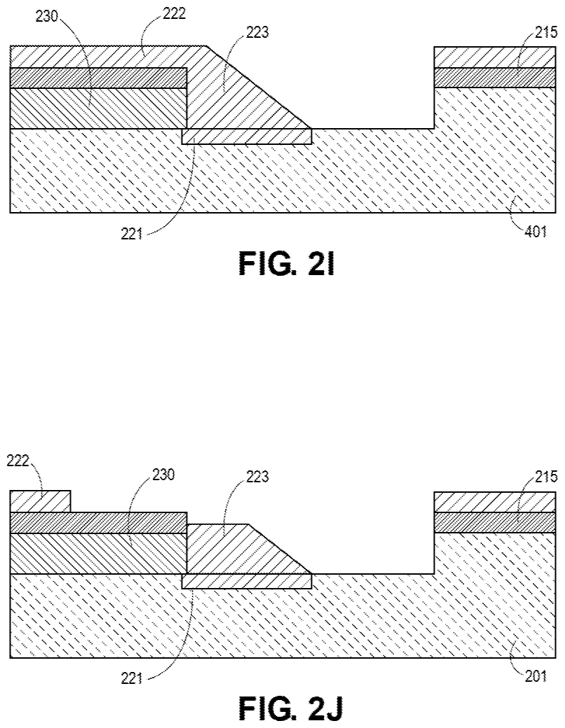

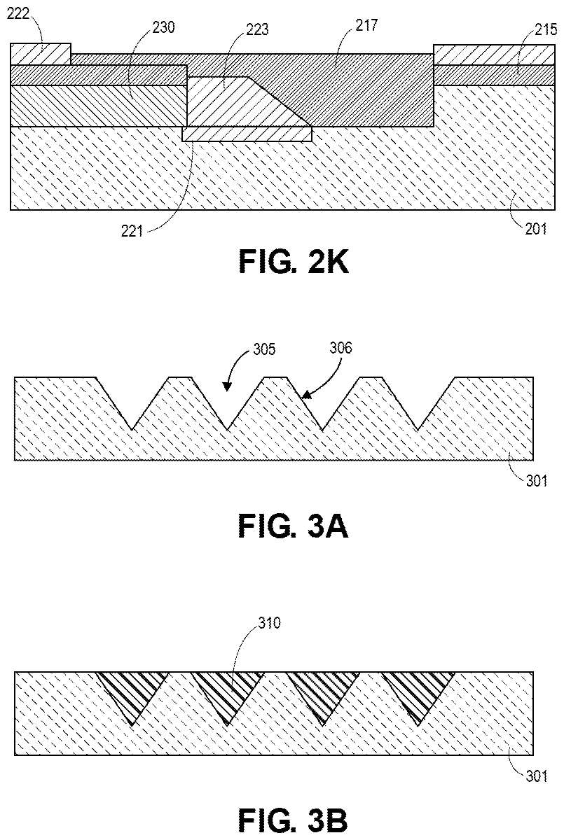

Referring now to FIGS. 2A-2K, a series of cross-sectional illustrations depicting a process for forming a closed system heat pipe is shown, in accordance with an embodiment. In an embodiment, the closed system heat pipe may have a structure similar to that of the micro channel structure described above, with the exception of the inlet and outlet being hermetically sealed.

Referring now to FIG. 2A, a cross-sectional illustration of a glass core 201 is shown, in accordance with an embodiment. In an embodiment, the glass core 201 may be substantially similar to the glass core 101 described in greater detail above. The glass core 201 may have a plurality of channels that are filled with a sacrificial layer 210. A lid 215 may be provided over the sacrificial layer 210. The sacrificial layer 210 may be a thermally decomposable material, and the lid 215 may be a metal, such as copper.

Referring now to FIG. 2B, a cross-sectional illustration of the glass core 201 along the dashed line in FIG. 2A is shown, in accordance with an embodiment. This cross-section shows an outlet of the channel. As shown, a gap is provided in the lid 215. The gap may be filled with the thermally decomposable sacrificial layer 210. Additionally, dielectric insert 221 may be provided at the bottom of the outlet of the channel.

Referring now to FIG. 2C, a cross-sectional illustration of the glass core 201 after a dielectric layer 222 is provided over the lid 215 and the glass core 201 is shown, in accordance with an embodiment. The dielectric layer 222 may be any suitable dielectric material. For example, the dielectric layer 222 may be a buildup film or the like. In an embodiment, the dielectric layer 222 is deposited with a lamination process or the like. In some embodiments, the dielectric layer 222 may be the same material as the dielectric insert 221. As shown, the dielectric layer 222 may be provided over a top surface of the lid 215 and sidewalls of the lid 215.

Referring now to FIG. 2D, a cross-sectional illustration of the glass core 201 along the dashed line in FIG. 2C is shown, in accordance with an embodiment. As shown, the dielectric layer 222 passes over the top surface of the sacrificial layer 210 exposed at the outlet of the channel.

Referring now to FIG. 2E, a cross-sectional illustration of the glass core 201 after the sacrificial layer 210 is removed is shown, in accordance with an embodiment. Removal of the sacrificial layer 210 opens up the channels 205 that are provided into the glass core 201. The sacrificial layer 210 may be removed with a thermal decomposition process, or any other suitable process that is selective to the sacrificial layer 210 over the other material layers.

Referring now to FIG. 2F, a cross-sectional illustration of the glass core 201 along the dashed line in FIG. 2E is shown, in accordance with an embodiment. As shown, the channel 205 is provided below the lid 215. An outlet of the channel 205 may extend up through the lid 215. Additionally, a portion of the dielectric layer 222 over the dielectric insert may be unsupported from below. As will be described in greater detail below, this architecture allows for the channel 205 to be sealed in a subsequent operation.

Referring now to FIG. 2G, a cross-sectional illustration of the glass core 201 after a cooling fluid 230 is supplied into the channels 205 is shown, in accordance with an embodiment. The cooling fluid may include water, or the like. The cooling fluid 230 may substantially fill the channels 205. In other embodiments, the cooling fluid 230 may partially fill the channels 205 in order to allow room for vapor or the like to be included in the channels 205.

Referring now to FIG. 2H, a cross-sectional illustration of the glass core 201 along the dashed line in FIG. 2G is shown, in accordance with an embodiment. As shown, the cooling fluid 230 substantially fills the channel 205.

Referring now to FIG. 2I, a cross-sectional illustration of the glass core 201 after the channel 205 is sealed is shown, in accordance with an embodiment. In an embodiment, the channel 205 may be sealed by pressing down the dielectric layer 222. As shown, the portion 223 cuts off the channel 205 and prevents the cooling fluid 230 from exiting the channel 205. In an embodiment, the portion 223 may connect with the dielectric insert 221. As such, a strong seal is provided to prevent leakage of the cooling fluid 230. The opposite side of the channel 205 is similarly closed in order to provide a sealed heat pipe.

Referring now to FIG. 2J, a cross-sectional illustration of the glass core 201 after a laser skiving process is shown, in accordance with an embodiment. As shown, the laser skiving process may remove a portion of the dielectric layer 222 so that the portion 223 is separated from the remainder of the dielectric layer 222. The portion 223 may have a substantially planar top surface and a sloping surface that extends down to the dielectric insert 221. A laser skiving process is one example of isolating the portion 223, but other patterning process may also be used in some embodiments.

Referring now to FIG. 2K, a cross-sectional illustration of the glass core 201 after the portion 223 is hermetically sealed is shown, in accordance with an embodiment. In an embodiment, the heat pipe may be sealed with a metallic plug 217, such as a copper plug 217. The plug 217 may be formed with a seed layer deposition process and an electroplating process. The plug 217 may cover the top surface and outer sidewall of the portion 223. The plug 217 may also be provided in contact with the lid 215 and the glass core 201.

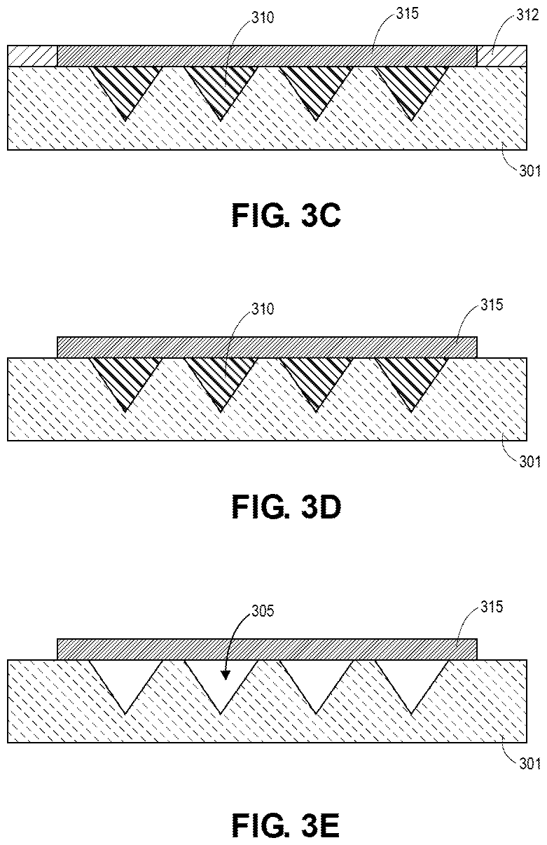

Referring now to FIGS. 3A-3E, a series of cross-sectional illustrations depicting a process for forming micro channels in a glass core is shown, in accordance with an embodiment. In an embodiment, the micro channels may be an open system. That is, a cooling fluid (e.g., water, etc.) may be flown into and out of the micro channels in order to cool the glass core. The micro channels may be provided proximate to one or more dies (not shown) or passive components (not shown) in order to remove heat from the system.

Referring now to FIG. 3A, a cross-sectional illustration of a glass core 301 is shown, in accordance with an embodiment. The glass core 301 may be any suitable glass formulation for making glass cores for package substrates. For example, the glass core 301 may be substantially similar to the glass core 101 described in greater detail above.

In an embodiment, channels 305 are formed into a top surface of the glass core 301 without passing entirely through a thickness of the glass core 301. For example, the channels 305 may have sidewall surfaces 306. The sidewall surfaces 306 may be sloped, so as to form a triangle shaped channel 305. In some embodiments, sloped sidewall surfaces 306 may be coupled together by a flat bottom surface (not shown), which provides a trapezoidal shaped channel 305. The channels 305 may extend into and out of the plane of FIG. 3A. In the illustrated embodiment, a set of four channels 305 are shown. Though, it is to be appreciated that one or more channels 305 may be used in some embodiments.

Referring now to FIG. 3B, a cross-sectional illustration of the glass core 301 after a sacrificial layer 310 is provided in the channels 305 is shown, in accordance with an embodiment. The sacrificial layer 310 may be used as a scaffolding on which a lid will be formed. The sacrificial layer 310 may be a dielectric material. In a particular embodiment, the sacrificial layer 310 is a material that is thermally decomposable. The sacrificial layer 310 may be deposited with any suitable deposition process, (e.g., lamination, printing, etc.). The top surfaces of the sacrificial layers 310 may be substantially coplanar with a top surface of the glass core 301.

Referring now to FIG. 3C, a cross-sectional illustration of the glass core 301 after a resist layer 312 is formed and patterned, and a lid 315 is formed over the sacrificial layer 310 is shown, in accordance with an embodiment. The resist layer 312 may be a photoresist material, or any other similarly patternable material. In an embodiment, the resist layer 312 may be deposited with a spin-on process, a deposition process, or any other suitable process. In an embodiment, the resist layer 312 is patterned by exposure to an electromagnetic radiation source. The resist layer 312 is then developed to remove portions of the resist layer from over one or more of the channels 305.

In an embodiment, the lid 315 may be any suitable material that prevents diffusion or leaking of a cooling fluid that will be flown through the channels 305. For example, the lid 315 may comprise copper in some embodiments. The lid 315 may be deposited with any suitable deposition process. For example, an electroplating process, a PVD process, a CVD process, or the like may be used in order to form the lid 315.

Referring now to FIG. 3D, a cross-sectional illustration of the glass core 301 after the resist layer 312 is removed is shown, in accordance with an embodiment. In an embodiment, the resist layer 312 may be removed with a resist stripping process, an ashing process, or any other suitable process.

Referring now to FIG. 3E, a cross-sectional illustration of the glass core 301 after the sacrificial layer 310 is removed is shown, in accordance with an embodiment. In an embodiment, the sacrificial layer 310 may be removed with a thermal decomposition process. For example, the glass core 301 may be placed in a volume that is maintained at an elevated temperature (e.g., approximately 200 degrees Celsius or higher). The sacrificial layer 310 decomposes and is removed out the inlet and/or outlet of the channels 305. After the sacrificial layer 310 is removed, a cooling fluid (e.g., water or the like) may be flown through the channels 305 in order to remove thermal energy from the system. The channels 305 in FIG. 3E may be referred to as micro channels in some embodiments, especially when the channels have a width and/or depth that is on the micron scale (e.g., 500 μm or less, 100 μm or less, or 20 μm or less).

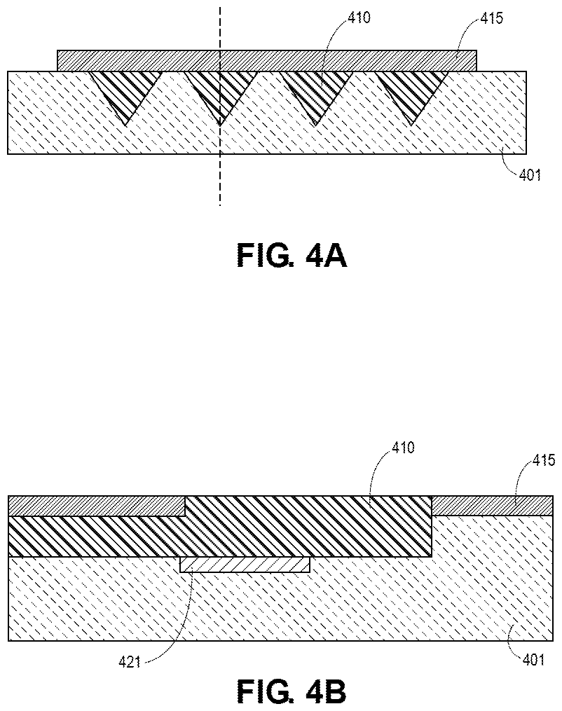

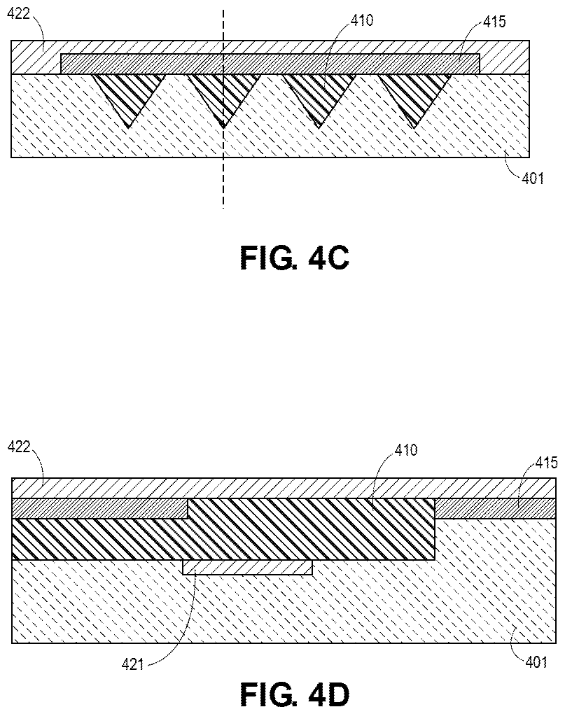

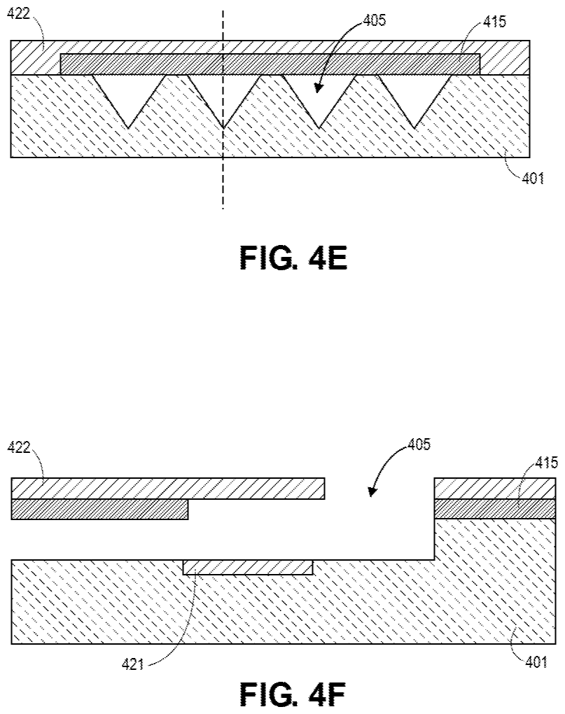

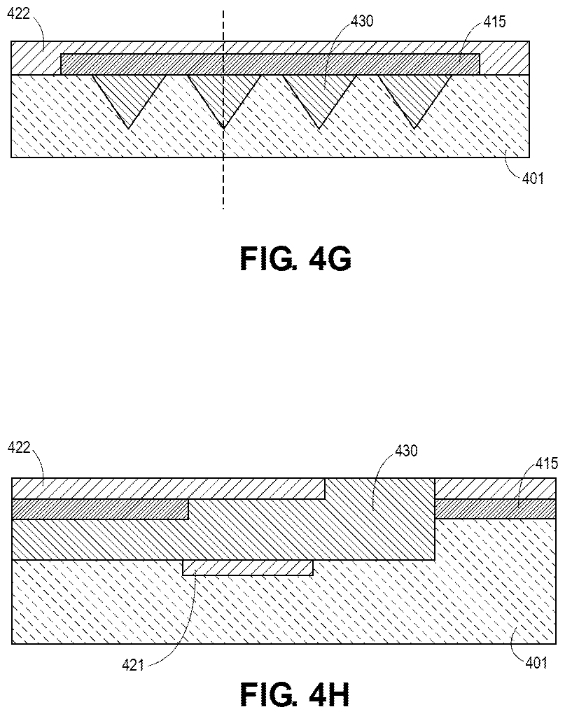

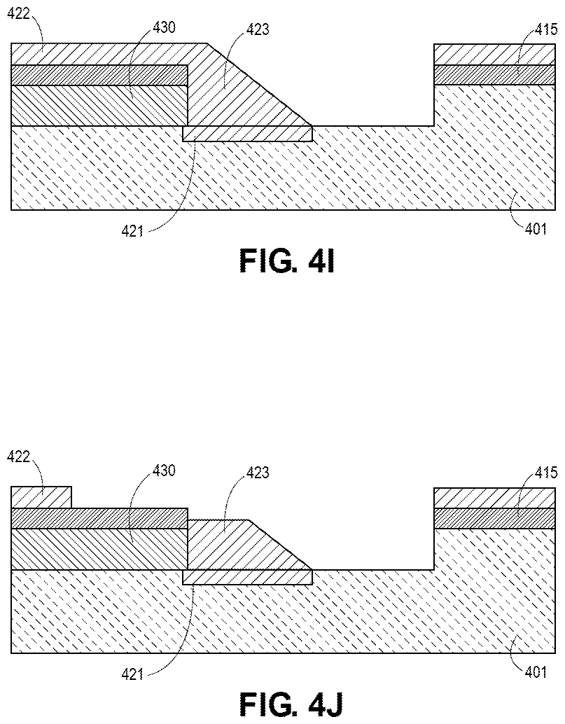

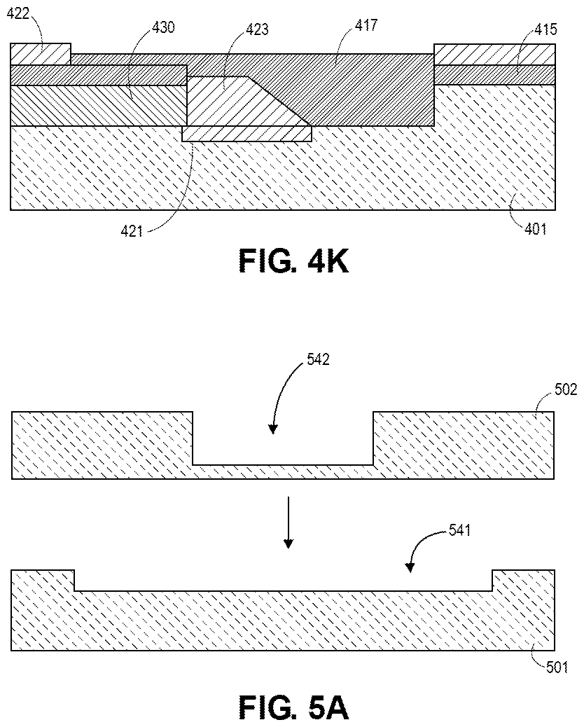

Referring now to FIGS. 4A-4K, a series of cross-sectional illustrations depicting a process for forming a closed system heat pipe is shown, in accordance with an embodiment. In an embodiment, the closed system heat pipe may have a structure similar to that of the micro channel structure described above, with the exception of the inlet and outlet being hermetically sealed.

Referring now to FIG. 4A, a cross-sectional illustration of a glass core 401 is shown, in accordance with an embodiment. In an embodiment, the glass core 401 may be substantially similar to the glass core 301 described in greater detail above. The glass core 401 may have a plurality of channels (e.g., triangular channels) that are filled with a sacrificial layer 410. A lid 415 may be provided over the sacrificial layer 410. The sacrificial layer 410 may be a thermally decomposable material, and the lid 415 may be a metal, such as copper.

Referring now to FIG. 4B, a cross-sectional illustration of the glass core 401 along the dashed line in FIG. 4A is shown, in accordance with an embodiment. This cross-section shows an outlet of the channel. As shown, a gap is provided in the lid 415. The gap may be filled with the thermally decomposable sacrificial layer 410. Additionally, dielectric insert 421 may be provided at the bottom of the outlet of the channel.

Referring now to FIG. 4C, a cross-sectional illustration of the glass core 401 after a dielectric layer 422 is provided over the lid 415 and the glass core 401 is shown, in accordance with an embodiment. The dielectric layer 422 may be any suitable dielectric material. For example, the dielectric layer 422 may be a buildup film or the like. In an embodiment, the dielectric layer 422 is deposited with a lamination process or the like. In some embodiments, the dielectric layer 422 may be the same material as the dielectric insert 421. As shown, the dielectric layer 422 may be provided over a top surface of the lid 415 and sidewalls of the lid 415.

Referring now to FIG. 4D, a cross-sectional illustration of the glass core 401 along the dashed line in FIG. 4C is shown, in accordance with an embodiment. As shown, the dielectric layer 422 passes over the top surface of the sacrificial layer 410 exposed at the outlet of the channel.

Referring now to FIG. 4E, a cross-sectional illustration of the glass core 401 after the sacrificial layer 410 is removed is shown, in accordance with an embodiment. Removal of the sacrificial layer 410 opens up the channels 405 that are provided into the glass core 401. The sacrificial layer 410 may be removed with a thermal decomposition process, or any other suitable process that is selective to the sacrificial layer 410 over the other material layers.

Referring now to FIG. 4F, a cross-sectional illustration of the glass core 401 along the dashed line in FIG. 4E is shown, in accordance with an embodiment. As shown, the channel 405 is provided below the lid 415. An outlet of the channel 405 may extend up through the lid 415. Additionally, a portion of the dielectric layer 422 over the dielectric insert may be unsupported from below. As will be described in greater detail below, this architecture allows for the channel 405 to be sealed in a subsequent operation.

Referring now to FIG. 4G, a cross-sectional illustration of the glass core 401 after a cooling fluid 430 is supplied into the channels 405 is shown, in accordance with an embodiment. The cooling fluid may include water, or the like. The cooling fluid 430 may substantially fill the channels 405. In other embodiments, the cooling fluid 430 may partially fill the channels 405 in order to allow room for vapor or the like to be included in the channels 405.

Referring now to FIG. 4H, a cross-sectional illustration of the glass core 401 along the dashed line in FIG. 4G is shown, in accordance with an embodiment. As shown, the cooling fluid 430 substantially fills the channel 405.

Referring now to FIG. 4I, a cross-sectional illustration of the glass core 401 after the channel 405 is sealed is shown, in accordance with an embodiment. In an embodiment, the channel 405 may be sealed by pressing down the dielectric layer 422. As shown, the portion 423 cuts off the channel 405 and prevents the cooling fluid 430 from exiting the channel 405. In an embodiment, the portion 423 may connect with the dielectric insert 421. As such, a strong seal is provided to prevent leakage of the cooling fluid 430. The opposite side of the channel 405 is similarly closed in order to provide a sealed heat pipe.

Referring now to FIG. 4J, a cross-sectional illustration of the glass core 401 after a laser skiving process is shown, in accordance with an embodiment. As shown, the laser skiving process may remove a portion of the dielectric layer 422 so that the portion 423 is separated from the remainder of the dielectric layer 422. The portion 423 may have a substantially planar top surface and a sloping surface that extends down to the dielectric insert 421. A laser skiving process is one example of isolating the portion 423, but other patterning process may also be used in some embodiments.

Referring now to FIG. 4K, a cross-sectional illustration of the glass core 401 after the portion 423 is hermetically sealed is shown, in accordance with an embodiment. In an embodiment, the heat pipe may be sealed with a metallic plug 417, such as a copper plug 417. The plug 417 may be formed with a seed layer deposition process and an electroplating process. The plug 417 may cover the top surface and outer sidewall of the portion 423. The plug 417 may also be provided in contact with the lid 415 and the glass core 401.

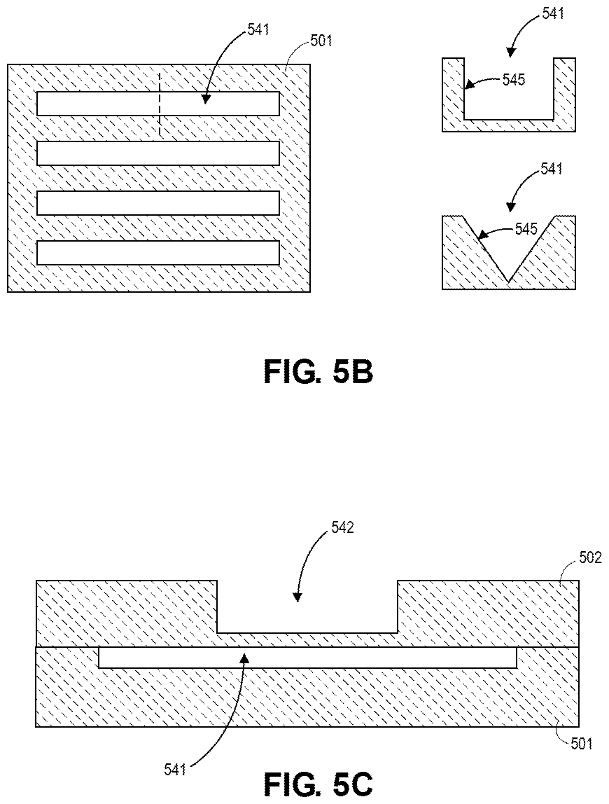

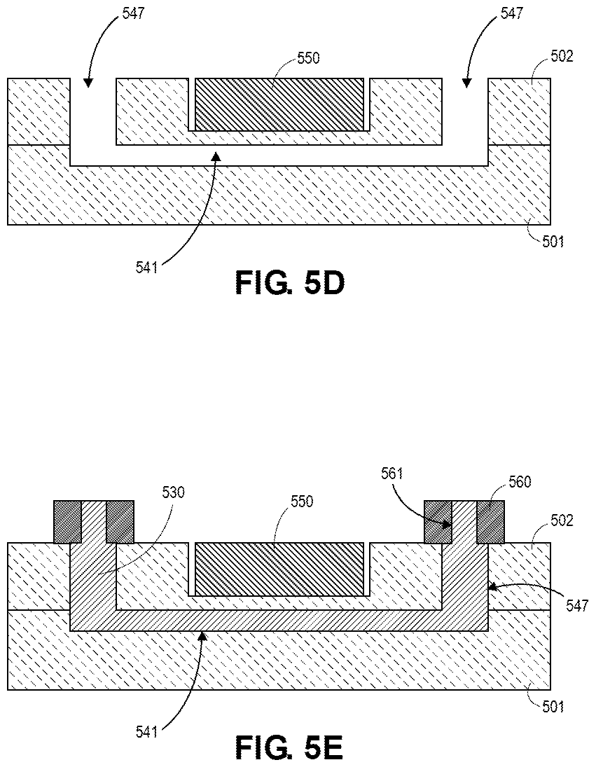

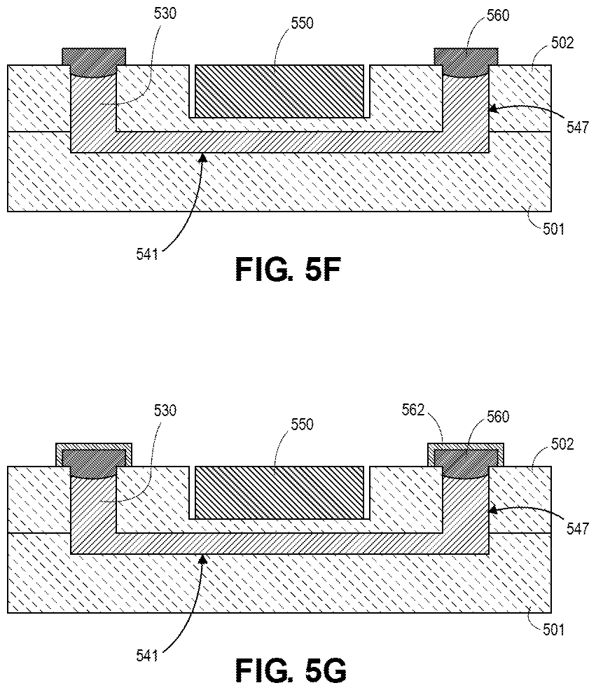

Referring now to FIGS. 5A-5G, a series of cross-sectional illustrations depicting a process for forming a glass core with a sealed heat pipe is shown, in accordance with an embodiment. The glass core in FIGS. 5A-5G includes a first portion 501 and a second portion 502. The channel 541 is provided into the first portion 501 and the second portion 502 seals the top of the channel 541. Openings through the second portion 502 provide fluidic access to the channel 541.

Referring now to FIG. 5A, a cross-sectional illustration of a glass core with a first portion 501 and a second portion 502 is shown, in accordance with an embodiment. As shown, a channel 541 may be formed into the top surface of the first portion 501. The second portion 502 has a flat bottom surface. As the second portion 502 is brought into contact with the first portion 501 (as indicated by the arrow), the second portion 502 seals the channel 541. In some embodiments, the second portion 502 may also include a cavity 542. The cavity 542 may be used to accommodate a die, a passive device, or the like.

Referring now to FIG. 5B, a plan view is on the left and a pair of cross-sectional illustrations on the right show the structure of the channel 541, in accordance with an embodiment. In an embodiment, a plurality of channels 541 may be provided substantially parallel with each other. In the cross-sectional illustrations on the right, the channels 541 are shown with either vertical sidewalls 545 or sloped sidewalls 545. The sloped sidewalls 545 may result in a channel 541 with a triangular shape. It is to be appreciated that the structure may include either type of channel 541 shown in FIG. 5B.

Referring now to FIG. 5C, a cross-sectional illustration of the glass core after the first portion 501 is attached to the second portion 502 is shown, in accordance with an embodiment. The first portion 501 may be adhered to the second portion 502 with any bonding architecture. In some embodiments, the first portion 501 and the second portion 502 may be bonded with a diffusion bonding process. In other embodiments, an adhesive may be provided between the first portion 501 and the second portion 502.

Referring now to FIG. 5D, a cross-sectional illustration of the glass core after a component 550 is inserted into the cavity 542 is shown, in accordance with an embodiment. The cavity 542 may be sized to receive a die, a passive component, or the like. In some embodiments, the component 550 generates a hot spot in the core that can be minimized by the use of the underlying channel 541. Also shown in FIG. 5D is the formation of inlets/outlets 547. The inlets/outlets 547 may be formed with a drilling process (e.g., laser drilling), etching, or the like. In an embodiment, the width of the inlets/outlets 547 may be greater than a depth of the channel 541. Additionally, while shown as having vertical sidewalls, the inlets/outlets 547 may also have sloped sidewalls in some embodiments.

At the point in FIG. 5D, the inlets/outlets 547 may be coupled to a fluid source in order to flow a cooling fluid (not shown) through the glass core. Such an embodiment may be referred to as being an open system solution, and the channel 541 may be referred to as a micro channel.

However, in other embodiments, the system may be further processed in order to seal the channel 541 to provide a closed system solution. Such an embodiment may be referred to as being a heat pipe or a micro heat pipe.

Referring now to FIG. 5E, a cross-sectional illustration of the glass core after a cooling fluid 530 is supplied in the channel 541 and inlets/outlets 547 is shown, in accordance with an embodiment. The cooling fluid 530 may be water or any other suitable heat transfer fluid or fluids. In an embodiment, caps 560 may be provided over the inlets/outlets 547. The caps 560 may include an opening 561 through which the cooling fluid 530 can be dispensed. The caps 560 may be a deformable material, such as a buildup film or the like.

Referring now to FIG. 5F, a cross-sectional illustration of the glass core after the caps 560 are sealed is shown, in accordance with an embodiment. In an embodiment, the caps 560 may be sealed by pressing down on the caps 560 to deform them. The deformed caps 560 may partially fill the inlets/outlets 547 to seal in the cooling fluid 530.

Referring now to FIG. 5G, a cross-sectional illustration of the glass core after hermetic seals 562 are provided over the caps 560 is shown, in accordance with an embodiment. In an embodiment, the hermetic seals 562 may comprise a metallic layer, such as copper or the like.

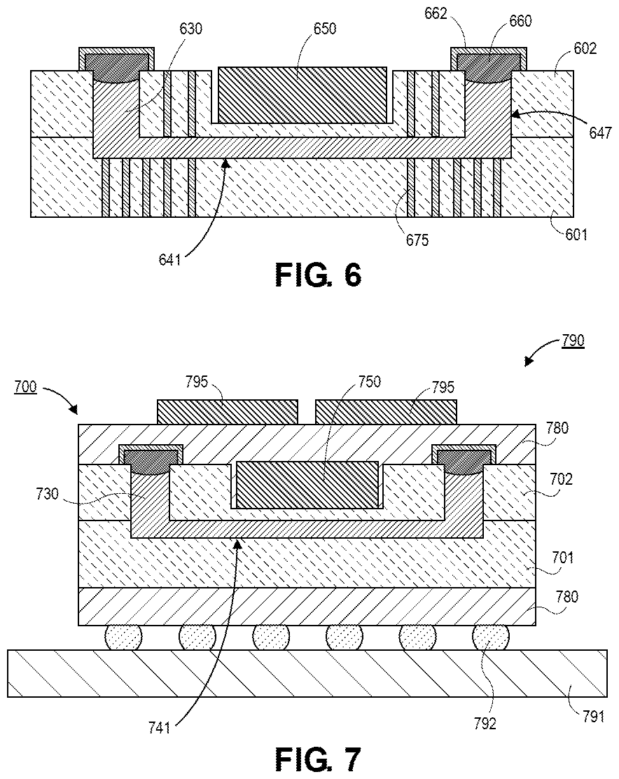

Referring now to FIG. 6, a cross-sectional illustration of a glass core is shown, in accordance with an additional embodiment. As shown, the glass core may comprise a first portion 601 and a second portion 602. A channel 641 with inlets/outlets 647 may be provided in the first portion 601 and the second portion 602. The channel 641 and inlets/outlets 647 may be filled with a cooling fluid 630. The inlets/outlets 647 may be sealed with a cap 660 and a hermetic seal 662. A component 650 may be provided in a cavity over the channel 641.

In addition to providing heat spreading with the heat pipe formed in the glass core, further thermal dissipation may be provided through the use of thermally conductive vias 675 that are formed in the first portion 601 and the second portion 602. For example, the thermally conductive vias 675 may comprise copper or the like.

Referring now to FIG. 7, a cross-sectional illustration of a computing system 790 is shown, in accordance with an embodiment. In an embodiment, the computing system 790 may comprise a board 791, such as a printed circuit board (PCB). The board 790 may be coupled to an electronic package 700 by interconnects 792, such as solder balls, sockets, or the like.

In an embodiment, the electronic package 700 may comprise a glass core. In the illustrated embodiment, the glass core comprises a first portion 701 and a second portion 702. A heat pipe 741 with a cooling fluid 730 is provided within the first portion 701 and the second portion 702. A component 750 may be provided in a cavity in the second portion 702. Buildup layers 780 may be provided above and below the glass core to provide electrical routing (not shown). For example, electrical routing may couple together overlying dies 795 through the component 750.

In the illustrated embodiment, the glass core is similar to the glass core described in greater detail with respect to FIGS. 5A-5G. However, it is to be appreciated that similar computing systems 790 may be formed with electronic packages 700 that include any of the glass core architectures described in greater detail herein.

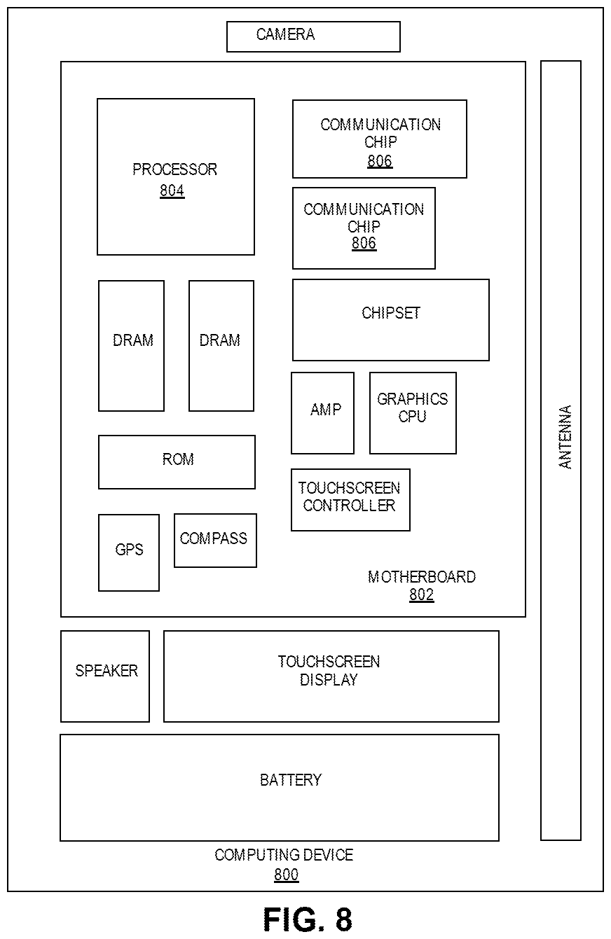

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises a glass core with a micro channel or micro heat pipe that is configured to hold a cooling fluid to actively cool components on or in the glass core, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises a glass core with a micro channel or micro heat pipe that is configured to hold a cooling fluid to actively cool components on or in the glass core, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a core with a first surface and a second surface opposite from the first surface, wherein the core comprises glass; a channel disposed into the first surface of the core; and a lid over the channel, wherein the lid seals the channel between a first end and a second end of the channel.

Example 2: the electronic package of Example 1, wherein the channel has vertical sidewalls.

Example 3: the electronic package of Example 1, wherein the channel has sloped sidewalls.

Example 4: the electronic package of Example 3, wherein the channel is triangular shaped.

Example 5: the electronic package of Examples 1-4, wherein a first end of the channel is coupled to fluid input, and wherein a second end of the channel is coupled to a fluid output.

Example 6: the electronic package of Examples 1-4, wherein a first end of the channel and a second end of the channel are both hermetically sealed with seals.

Example 7: the electronic package of Example 6, wherein the seal comprises a buildup film with a metallic layer over the buildup film.

Example 8: the electronic package of Example 7, wherein the buildup film has a sloped surface.

Example 9: the electronic package of Example 7 or Example 8, wherein a cooling fluid is hermetically sealed within the channel.

Example 10: an electronic package, comprising: a core with a first portion and a second portion, wherein the first portion is adhered to the second portion; a channel in the first portion of the core, wherein a top of the channel is covered by a bottom surface of the second portion; and vertical openings through the second portion that are fluidically coupled to the channel.

Example 11: the electronic package of Example 10, wherein a width of the vertical openings is greater than a depth of the channel.

Example 12: the electronic package of Example 10 or Example 11, wherein the channel has vertical sidewalls.

Example 13: the electronic package of Example 10 or Example 11, wherein the channel has sloped sidewalls.

Example 14: the electronic package of Examples 10-13, further comprising: a cavity into the second portion of the core, wherein a component is disposed in the cavity.

Example 15: the electronic package of Examples 10-14, wherein the vertical openings are hermetically sealed.

Example 16: the electronic package of Example 15, wherein a cooling fluid is provided in the channel and the vertical openings.

Example 17: the electronic package of Examples 10-16, further comprising: pillars through the core.

Example 18: a computing system, comprising: a board; and a package substrate coupled to the board, wherein the package substrate comprises: a core, wherein the core comprises glass; a fluidic path within the core; and a lid to seal the fluidic path between a first end of the fluidic path and a second end of the fluidic path.

Example 19: the computing system of Example 18, wherein the first end of the fluidic path and the second end of the fluidic path are both sealed.

Example 20: the computing system of Example 18 or Example 19, wherein the computing system is part of a personal computer, a server, a mobile device, a tablet, or an automobile.

What is claimed is:

1. An electronic package, comprising:
a core with a first surface and a second surface opposite from the first surface, wherein the core comprises glass;
a channel disposed into the first surface of the core; and
a lid over the channel, wherein the lid seals the channel between a first end and a second end of the channel.

2. The electronic package of claim 1, wherein the channel has vertical sidewalls.

3. The electronic package of claim 1, wherein the channel has sloped sidewalls.

4. The electronic package of claim 3, wherein the channel is triangular shaped.

5. The electronic package of claim 1, wherein a first end of the channel is coupled to fluid input, and wherein a second end of the channel is coupled to a fluid output.

6. The electronic package of claim 1, wherein a first end of the channel and a second end of the channel are both hermetically sealed with seals.

7. The electronic package of claim 6, wherein the seal comprises a buildup film with a metallic layer over the buildup film.

8. The electronic package of claim 7, wherein the buildup film has a sloped surface.

9. The electronic package of claim 7, wherein a cooling fluid is hermetically sealed within the channel.

10. An electronic package, comprising:
a core with a first portion and a second portion, wherein the first portion is adhered to the second portion;
a channel in the first portion of the core, wherein a top of the channel is covered by a bottom surface of the second portion; and
vertical openings through the second portion that are fluidically coupled to the channel.

11. The electronic package of claim 10, wherein a width of the vertical openings is greater than a depth of the channel.

12. The electronic package of claim 10, wherein the channel has vertical sidewalls.

13. The electronic package of claim 10, wherein the channel has sloped sidewalls.

14. The electronic package of claim 10, further comprising:
a cavity into the second portion of the core, wherein a component is disposed in the cavity.

15. The electronic package of claim 10, wherein the vertical openings are hermetically sealed.

16. The electronic package of claim 15, wherein a cooling fluid is provided in the channel and the vertical openings.

17. The electronic package of claim 10, further comprising:
pillars through the core.

18. A computing system, comprising:
a board; and
a package substrate coupled to the board, wherein the package substrate comprises:
a core, wherein the core comprises glass;
a fluidic path within the core; and
a lid to seal the fluidic path between a first end of the fluidic path and a second end of the fluidic path.

19. The computing system of claim 18, wherein the first end of the fluidic path and the second end of the fluidic path are both sealed.

20. The computing system of claim 18, wherein the computing system is part of a personal computer, a server, a mobile device, a tablet, or an automobile.
